(19) United States
(12) Patent Application Publication
(10) Pub. No.: US 2014/0187052 A1
(43) Pub. Date: Jul. 3, 2014

(54) Selective Etching of Hafnium Oxide Using Diluted Hydrofluoric Acid

(71) Applicant: INTERMOLECULAR INC., San Jose, CA (US)

(72) Inventor: Gregory Nowling, San Jose, CA (US)

(73) Assignee: Intermolecular Inc., San Jose, CA (US)

(21) Appl. No.: 13/727,776

(22) Filed: Dec. 27, 2012

(51) Int. Cl. H01L 21/306

(52) U.S. Cl. CPC H01L 21/30604
USPC 438/756; 438/757

(57) ABSTRACT

Provided are methods for processing semiconductor substrates having hafnium oxide structures as well as silicon nitride and/or silicon oxide structures. Etching solutions and processing conditions described herein provide high etching selectivity of hafnium oxide relative to these other materials. As such, the hafnium oxide structures can be removed (partially or completely) without significant damage to these other structures. In some embodiments, the etching selectivity of hafnium oxide relative to silicon oxide is at least about 10 and even at least about 30. Etching rates of hafnium oxide may be between 3 and 100 Angstroms per minute. A highly diluted water based solution of hydrofluoric acid, e.g., having a dilution ratio of 1000:1 to 10,000:1, may be used for etching to achieve these etching rates and selectivity levels. The solution may be maintained at a temperature of 25° C. to 90° C. during etching.

### BACKGROUND

Semiconductor devices have dramatically decreased in size in recent years. Some modern devices include features that are less than 100 nanometers in size, e.g., 45 nanometers and/or 32 nanometers. As device and feature sizes continue to shrink, processing methods and materials need to be improved.

Hafnium oxide found various uses in semiconductor devices. Hafnium oxide is a candidate for gate oxides applications in field effect transistors (FETs). Such use of hafnium oxide helps reducing power consumption due to lower gate current leakage. Hafnium oxides are also used for optical coating and memory applications.

Hafnium oxide components often need to be etched without damaging other surrounding components. For example, when hafnium oxide is used as a gate oxide, an initially formed hafnium oxide structure may need to be undercut to allow uniform deposition of a liner and spacers. At the same time, adjacent silicon oxide and/or silicon nitride structures should be preserved. Wet etching is commonly used in the semiconductor industry for selective removal of various materials within complex integrated circuit structures. High selectivity is generally needed to ensure that one structure is removed without damaging other structures exposed to the same etching solution.

### SUMMARY

Provided are methods for processing semiconductor substrates having hafnium oxide structures as well as silicon nitride and/or silicon oxide structures. Etching solutions and processing conditions described herein provide high etching selectivity of hafnium oxide relative to these other materials. As such, the hafnium oxide structures can be removed (partially or completely) without significant damage to these other structures. In some embodiments, the etching selectivity of hafnium oxide relative to silicon oxide is at least about 10 and even at least about 30. Etching rates of hafnium oxide may be between 3 and 100 Angstroms per minute. A highly diluted water based solution of hydrofluoric acid, e.g., having a dilution ratio of 1000:1 to 10,000:1, may be used for etching to achieve these etching rates and selectivity levels. The solution may be maintained at a temperature of 25° C. to 90° C. during etching.

In some embodiments, a method for processing semiconductor substrates involves providing a semiconductor substrate having a first structure and a second structure. The first structure may include hafnium oxide, while the second structure may include silicon nitride or silicon oxide. In some embodiments, the substrate includes all three types of structures, i.e., a hafnium oxide structure, a silicon nitride structure, and a silicon oxide structure. The substrate may also include other structures, such as polysilicon, titanium oxide, titanium nitride, silicide (e.g., NiSi, SiGe), and other types of structures.

The method then proceeds with exposing the semiconductor substrate to an etching solution. The etching solution may include hydrofluoric acid and water such that a volumetric dilution ratio of water to hydrofluoric acid is between 1,000:1 and 10,000:1. In some embodiments, the dilution ratio is about 5,000:1 or about 3,000:1. The dilution ratio may be also between 1,000:1 and 5,000:1 or between 5,000:1 and 10,000:1. In some embodiments, the dilution ratio is between 1,000:1 and 3,000:1 or between 3,000:1 and 10,000:1. In general, dilution of hydrofluoric acid in water increases etching selectivity of hafnium oxide relative to silicon nitride and/or silicon oxide as further described above. However, dilution also tends to decrease the etching rate of hafnium oxide and thereby slowing the overall etching operation. The optimal dilution may vary depending on other components exposed to the etching solution.

Once the semiconductor substrate is exposed to the etching solution, the process continues with etching the hafnium oxide structure, which is referred to as the first structure. Overall, the first structure is the one that needs to be partially or completely removed, while the second structure is the one that needs to be preserved. The second structure may include silicon oxide and/or silicon nitride. The etching rate of the first structure is greater than the etching rate of the second structure. In other words, the etching selectivity of the second structure relative to the first structure is less than one. In some embodiments, this selectivity is less than about 0.7, less than 0.5, less than 0.2, and even less than 0.1. For purposes of this document, etching selectivity is defined as a ratio of two etching rates. As such, the etching rate of the second structure is about 1.5 times less than the etching rate of the first structure. More specifically, the etching rate of the second structure is about 2 times less, about 5 times less, and even about 10 times less than the etching rate of the first structure. In some embodiments, etching of the first structure may be completed without substantial deterioration of the second structure, e.g., the second structure loosing less than 5% of its thickness.

The etching solution may be held at a temperature of between 25° C. and 90° C. while etching the first structure. More specifically, the etching solution may be maintained at between 40° C. and 60° C. The temperature may have some impact on the etching selectivity. The increase in temperature may also help increasing the etching rates thereby speeding up the overall process. However, excessive temperatures may cause evaporation of some components (e.g., water) from the etching solution and effectively changing the composition of the solution resulting in less favorable performance. In some embodiments, the etching rate of the first structure is between 3 Angstroms per minute and 100 Angstroms per minute or, more specifically, between 10 Angstroms per minute and 100 Angstroms per minute. The etching rate of the first structure may be less than 50 Angstroms per minute or even less than 20 Angstroms per minute.

The etching rates may depend on techniques used to form structures. For example, silicon oxide structures formed by thermal oxidation may perform differently than silicon oxide structured formed by plasma enhanced chemical vapor deposition (PECVD). In some embodiments, the second structure includes silicon oxide. This structure may be formed by thermal oxidation of silicon substrate. The etching rate of this structure is at least 50 times less than the etching rate of the hafnium oxide structure. In some embodiments, the hafnium oxide structure is deposited using atomic layer deposition (ALD), chemical vapor deposition (CVD), or physical vapor deposition (PVD). Alternatively, a silicon oxide structure may be formed using PECVD. The etching rate of this structure may be between 2 and 10 less than the etching rate of the hafnium oxide structure. Furthermore, the second structure may include silicon nitride. This structure may be formed using low pressure chemical vapor deposition (LPCVD). The etching rate of this structure may be between 1.5 and 6 less than the etching rate of the hafnium oxide structure.

In some embodiments, the hafnium oxide structure is only partially removed during its etching. In order to precisely control the thickness of the remaining structure the etching rates of the first structure should be sufficiently low, e.g., less than about 100 Angstroms per minute, less than 50 Angstroms per minute, and even less than about 20 Angstroms per minute. The etching rates may be kept low in order to control removal of hafnium oxide. Furthermore, low etching rates generally result from using more diluted hydrofluoric acid and/or low temperatures, which corresponds to improve selectivity of hafnium oxide to silicon nitride.

In some embodiments, the etching solution also includes hydrochloric acid. The hydrochloric acid may be used to adjust the pH of the etching solution, which in some embodiments, is between 0 pH to 3 pH. Addition of hydrochloric acid to a mixture of hydrofluoric acid and water increases formation of mono-fluorides (i.e., HF), which are the species that etch hafnium oxide that di-fluorides (i.e., H₂F₂) that tend to etch silicon oxides. As such, the selectivity may be improved. In some embodiments, a method for processing semiconductor substrates involves providing a semiconductor substrate having a hafnium oxide structure and a silicon oxide structure. The two structures may form a portion of a metal oxide semiconductor (MOS) transistor device. The method may proceed with exposing the semiconductor substrate to an etching solution. The etching solution includes hydrofluoric acid and water such that a volumetric dilution ratio of water to hydrofluoric acid in the etching solution is between 1,000:1 and 10,000:1. The process continues with partially etching the hafnium oxide structure at a higher etching rate than the silicon oxide structure. The etching rate of the silicon oxide structure may be at least 10 times less than the etching rate of the hafnium oxide structure. In some embodiments, the etching rate of the hafnium oxide structure is between 3 Angstroms per minute and 20 Angstroms per minute.

These and other embodiments are described further below with reference to the figures.

### BRIEF DESCRIPTION OF THE DRAWINGS

FIGS. 1A and 1B illustrate schematic representations of semiconductor substrate portions before and after etching of a hafnium oxide structure, in accordance with some embodiments.

FIG. 2 illustrates a process flowchart corresponding to a method of processing a semiconductor substrate to remove hafnium oxide structures using highly diluted hydrofluoric acid solutions, in accordance with some embodiments.

FIG. 3 illustrates plots of etching selectivity values of hafnium oxide to thermal silicon oxide as a function of a dilution rate, each plot corresponding to a different temperature of the etching solutions.

FIG. 4 illustrates a schematic representation of an etching apparatus for processing a semiconductor substrate to remove hafnium oxide structures using highly diluted hydrofluoric acid solutions, in accordance with some embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

Scaling of the gate lengths and equivalent gate oxide thicknesses leads to evaluation of new materials to replace silicon oxide as a gate dielectric. The desired materials need to have high-dielectric constants (i.e., high-k materials) to reduce leakage of currents and need to meet strict reliability requirements. Some additional characteristics include silicon related band offsets, permittivity, dielectric breakdown strength, interface stability and quality with silicon, and the carrier effective masses.

Hafnium oxide is believed to be a strong candidate for replacing silicon oxide as a gate dielectric material. Hafnium oxide has a dielectric constant of about 25 at room temperature, or about six times greater than that of silicon oxide. Furthermore, hafnium oxide has a conduction band offset of about 1.5-2.0 eV with respect to silicon, which is more than one order of magnitude higher than that of strontium titanium oxide, which is another material with a relative large dielectric constant.

The same properties that make hafnium oxide a strong candidate for a gate dielectric application also give hafnium oxide a good potential for other applications, such as insulating dielectrics in capacitive elements of various memory devices or, more specifically, of dynamic random-access memory (DRAM) capacitor stacks. Because of its high dielectric constants, a thick film of hafnium oxide can be used to achieve the same performance as a much thinner silicon dioxide layer but with much lower leakage currents. In addition to having a high dielectric constant, hafnium oxide is thermodynamically stable with respect to silicon, with which it may be in contact in many semiconductor applications. Many modern complementary metal-oxide-semiconductor (CMOS) and DRAM processes involve high temperatures (e.g., 1000° C.) that are applied to substrates for a few seconds. Some other applications of hafnium oxide include optical coatings, catalysts, and protective coatings (due to its hardness and thermal stability).

Hafnium oxide layers or structures may be deposited by a variety of physical vapor deposition (PVD) methods, including laser pulse ablation and sputtering. For example, hafnium metallic targets may be sputtered in an oxygen containing environment. Specifically, a hafnium oxide layer may be formed using reactive sputtering by employing a metal hafnium target in a 20-60% oxygen atmosphere. Power of 100-1000 Watts (W) may be used to achieve deposition rates of between about 0.1 and 1.0 Angstroms per second.

Other deposition techniques include chemical vapor deposition (CVD) using β-diketonate precursors, alkoxide precursors, and chloride precursors. Atomic layer deposition (ALD) techniques may be used to prepare films using both chloride and iodide precursors. Examples of CVD and ALD precursors that can be used to form hafnium oxide structures include bis(tert-butylcyclopentadienyl) dimethyl hafnium (C₂₀H₃₂Hf), bis(methyl-η5-cyclopentadienyl) dimethyl hafnium (Hf[C₅H₄(CH₃)]₂(CH₃)₂), bis(methyl-η5-cyclopentadienyl) methoxymethyl hafnium (HfCH₃(OCH₃)[C₅H₄ (CH₃)]₂, bis(trimethylsilyl) amidohafnium chloride ([[(CH₃)₃Si]₂N]₂HfCl₂), and dimethyl bis(cyclopentadienyl) hafnium ((C₅H₅)₂Hf(CH₃)₂), hafnium tert-butoxide (Hf[OC(CH₃)₃]₄), hafnium isopropoxide isopropanol adduct (C₁₂H₂₈HfO₄), tetrakis(diethylamido) hafnium ([(CH₂CH₃)₂N]₄Hf, tetrakis(dimethylamido) hafnium ([(CH₃)₂N]₄Hf), and tetrakis(ethylmethylamido) hafnium ([(CH₃)(C₂H₅)N]₄Hf). It should be noted that different deposition techniques yield different film structures that may have different susceptibilities to etching.

Provided methods involve at least partial removal of hafnium oxide structures using water-based etching solutions while preserving other structures provided on the same substrate. For purposes of this disclosure, full or partial removal of the hafnium oxide structures is collectively referred to as etching. The difference between full or partial removal depends on the size and shape of the structure, etching rate, and etching duration. A hafnium oxide structure may be used as a gate dielectric, a high-k dielectric in DRAM capacitors, and other like devices.

In addition to one or more hafnium oxide structures, the processed substrate includes one or more of silicon nitride or silicon oxide structures. Other types of structures may include polysilicon and/or titanium nitride structures. For example, a method may be used to partially remove a hafnium oxide gate dielectric, which involves exposing silicon oxide STI structures to the same etching solution. Etching solutions and processing conditions described herein provide high etching selectivity of hafnium oxide relative to these other materials. As such, hafnium oxide structures may be partially or completely removed without significant deterioration of the other structures exposed to the etching solution.

Overall, the etching rate of hafnium oxide structures may be greater than the etching rate of other structures on the substrate, e.g., silicon oxide structures and/or silicon nitride structures. In other words, the etching selectivity of these other materials relative to hafnium oxide is less than one. In some embodiments, this selectivity is less than about 0.7, less than 0.5, less than 0.2, and even less than 0.1. As such, the etching rate of these other materials is about 1.5 times less than the etching rate of hafnium oxide or, more specifically, about 2 times less, about 5 times less, and even about 10 times less.

These levels of etching selectivity are achieved by diluting hydrofluoric acid to a certain level using water. For example, the selectivity of hafnium oxide to silicon oxide (formed using a thermal deposition) increases more than 15 fold, i.e., from 3.3 to 49.5, when the solution is diluted from the 1,000:1 ratio to the 5,000:1 ratio (of water to hydrofluoric acid). Very similar results were achieved with silicon oxide deposited using PECVD techniques. Selectivity of hafnium oxide to silicon nitride (formed using low pressure CVD or ALD) also increases with dilution, but to a lesser extent. As such, an etching solution using to remove hafnium oxide may have a dilution ratio of between 1000:1 and 10,000:1.

Any loss in etching rates due to more dilution may be compensated by raising the temperature of an etching solution. For example, hafnium oxide exposed to the 5,000:1 solution maintained at 25° C. has an etching rate of 1.7 Angstroms per minute. When the same solution is heated to 40° C., the etching rate increased to 2.2 Angstroms per minute. The etching rate is 3.8 Angstroms per minute at 60° C., and 6.9 Angstroms per minute at 80° C. Overall, the hafnium oxide etching rate in the 5,000:1 solution maintained at 80° C. is actually higher that the rate in the 1,000:1 solution maintained at 25° C., which is only 2.8 Angstroms per minute.

The etching selectivity of hafnium oxide to other components also improved with increase in temperature of the etching solution. For example, the etching selectivity of hafnium oxide to silicon oxide (formed using a thermal deposition) increases from 49.5 to 92.0 for the 5,000:1 solution when the temperature is increased from 25° C. to 80° C. In some embodiments, the etching solution may be held at a temperature of between 25° C. and 90° C. while etching the hafnium oxide structure or, more specifically, between 40° C. and 60° C. In some embodiments, the etching rate of hafnium oxide is between 3 Angstroms per minute and 100 Angstroms per minute or, more specifically, between 10 Angstroms per minute and 100 Angstroms per minute.

### Semiconductor Device Examples

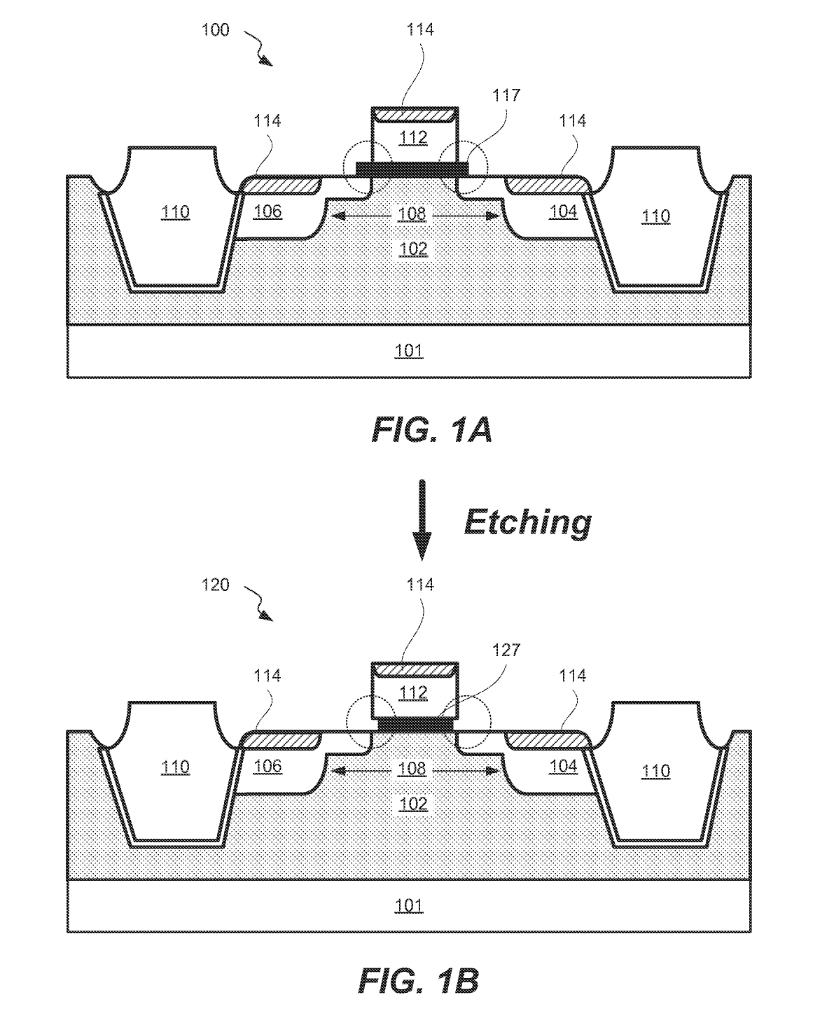

A brief description of semiconductor device examples is presented below to provide better understanding of various hafnium oxide etching and selectivity features. Specifically, FIGS. 1A and 1B illustrate schematic representations of substrate portions including MOS device 100 before partial removal of gate dielectric 117 and the same device 120 after such partial removal, in accordance with some embodiments. The references below are made to positive metal-oxide semiconductor (PMOS) devices but other types of MOS devices can be used in the described processes and will be understood by one having ordinary skill in the art. MOS device 100 includes a p-doped substrate 101 and an n-doped well 102 disposed within substrate 101. Substrate 101 is typically a part of an overall wafer that may include other devices. Some of these devices may include silicon nitride, silicon oxide, polysilicon, or titanium nitride structures that are exposed to an etching solution during partial removal of gate dielectric 117. P-doped substrate 101 may include any suitable p-type dopants, such as boron and indium, and may be formed by any suitable technique. N-doped well 102 may include any suitable n-type dopants, such as phosphorus and arsenic, and may be formed by any suitable technique. For example, n-doped well 102 may be formed by doping substrate 101 by ion implantation, for example.

MOS device 100 also includes a conductive gate electrode 112 that is separated from n-doped well 102 by gate dielectric 117. Gate electrode 112 may include any suitable conductive material. In one embodiment, gate electrode 112 may comprise polysilicon. In another embodiment, gate 112 may include polysilicon doped with a p-type dopant, such as boron. Gate dielectric 117 is formed from hafnium oxide. Hafnium oxide has a very high a dielectric constant and a large conduction band offset with respect to silicon as described above.

MOS device 100 also includes p-doped source region 104 and drain region 106 (or simply the source and drain) disposed in n-doped well 102. Source 104 and drain 106 are located on each side of gate electrode 112 forming channel 108 within n-doped well 102. Source 104 and drain 106 may include a p-type dopant, such as boron. Source 104 and drain 106 may be formed by ion implantation. After forming source 104 and drain 106, MOS device 100 may be subjected to an annealing and/or thermal activation process, which may impact etching characteristics of various components.

In some embodiment, source 104, drain 106, and gate electrode 112 are covered with a layer of self-aligned silicide portions 114, which may be also referred to as salicide portions or simply salicides. For example, a layer of cobalt may be deposited as a blanket film and then thermally treated to form these silicide portions 114. Other suitable materials include nickel and other refractory metals, such as tungsten, titanium, platinum, and palladium. After forming the blanket film from the suitable metal, the film is subjected to rapid thermal process (RTP) to react the metal with silicon contained within gate electrode 112, as well as within source 104 and drain 106, to form a metal silicide. The RTP process may be performed at 700° C. to 1000° C.

MOS device 100 may also include STI structures 110 disposed on both sides of source 104 and drain 106. STI structures 110 may include liners formed on the side and bottom walls by, for example, thermal oxidation of silicon of n-doped well 102. The main body of STI structures is formed by filling a trench within n-doped well 102 with a dielectric material, such as silicon oxide. Silicon oxide may be filled using high density plasma (HDP) deposition process.

As shown in FIG. 1A, gate dielectric 117 may protrude beyond gate electrode 112. As such, gate dielectric 117 may need to be partially etched such that it does not extend past electrode 112 and does not interfere with subsequent formation of liners and spacers on sidewalls of gate electrode 112. However, exposing portions of gate dielectric 117 to an etching solution will also expose other components, such as gate electrode 112 (which may be formed from polysilicon), STI structures (which may be formed from silicon oxide), as well as other structures (which may be formed from silicon nitride, silicon oxide, polysilicon, and/or titanium nitride). Etching of these components may need to be minimized.

FIG. 1B illustrates a schematic representation of MOS device 120 after partial removal of the gate dielectric 117, in accordance with some embodiments. Edges of a trimmed gate dielectric 127 (formed from gate dielectric 117) have been trimmed such that gate dielectric 127 does not extend away from gate electrode 112. MOS device 120 is ready for receiving a liner and spacers on the side walls of gate electrode 112 and over portions of source region 104 and drain region 106.

Other devices that include hafnium oxide structures and one or more structures formed from one of silicon nitride, silicon oxide, polysilicon, or titanium nitride are also within the scope of this disclosure. For example, a DRAM capacitor stack including a hafnium oxide dielectric and one or more electrodes formed from titanium nitride and/or doped polysilicon may be etched using techniques described herein.

### Processing Examples

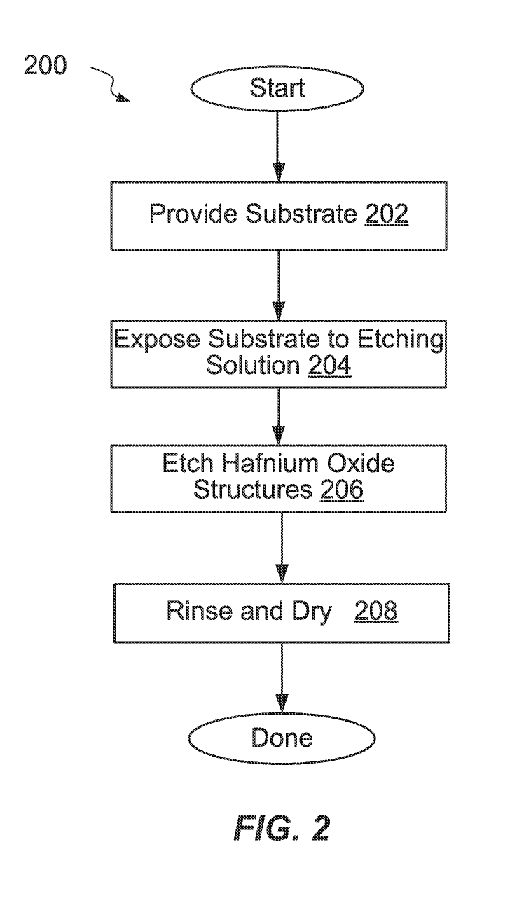

FIG. 2 illustrates a process flowchart corresponding to method 200 of processing a semiconductor substrate to at least partially remove hafnium oxide structures, in accordance with some embodiments. Method 200 may commence with providing a semiconductor substrate including a hafnium oxide structure (e.g., a first structure) and another structure formed from one of silicon nitride or silicon oxide (e.g., a second structure) during operation 202. Some substrate examples are described above with reference to FIGS. 1A and 1B. In some embodiments, the substrate has one or more additional structures (e.g., a third structure, a fourth structure) that include one of silicon nitride, silicon oxide, polysilicon, or titanium nitride. The materials of these other structures may be different from the material of the second structure. In some embodiments, one of these structures is formed by depositing silicon nitride using ALD or low pressure CVD or silicon oxide deposited using thermal oxidation or PECVD. As noted above, deposition techniques may impact etching rates and, as a result, etching selectivity of various materials.

Method 200 may proceed with exposing the semiconductor substrate to an etching solution during operation 204. Specifically, the etching solution comes in contact with the hafnium oxide structure and one or more other structures. As stated above, the etching solution includes a highly diluted hydrofluoric acid. Specifically, the dilution ratio of water to hydrofluoric acid may be between 1,000:1 and 10,000:1 by volume. In some embodiments, the dilution ratio is about 5,000:1 or about 3,000:1. The dilution ratio may be also between 1,000:1 and 5,000:1 or between 5,000:1 and 10,000:1. In some embodiments, the dilution ratio may be also between 1,000:1 and 3,000:1 or between 3,000:1 and 10,000:1. The dilution ratio may depend on types of other structures. For example, etching selectivity of hafnium oxide relative to silicon oxide improves substantially with dilution, while etching selectivity of hafnium oxide relative to silicon nitride tends to remain the same.

In some embodiments, the etching solution may also include hydrochloric acid. Hydrochloric acid may be added to adjust the acidity of the acidity of the solution, which, in some embodiments, may be between about 1 pH and 3 pH. The addition of solid silicon, or silica to the mixture containing hydrofluoric acid may also increase the hafnium oxide to silicon oxide selectivity. Polar solvents, such as ethylene glycol, may be used as well.

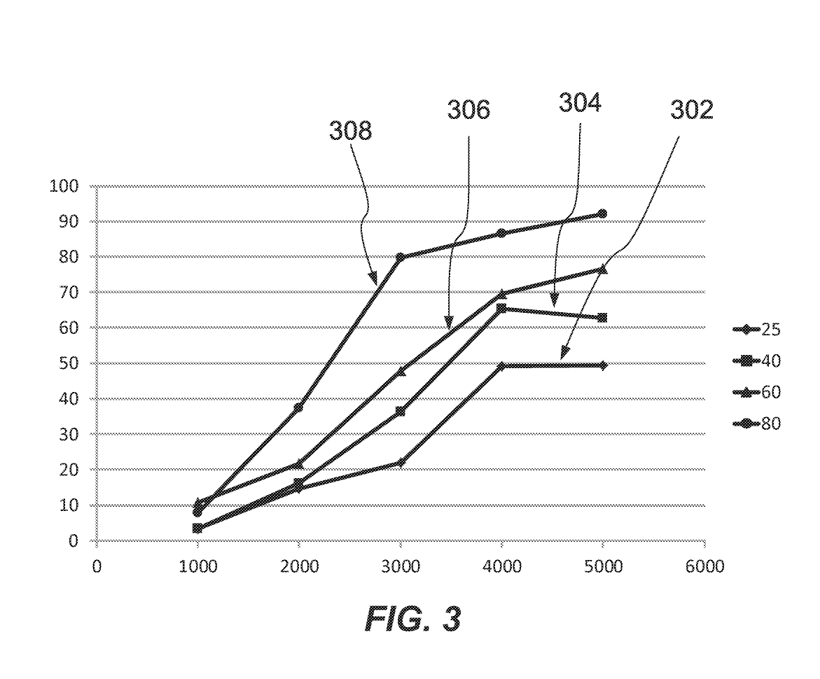

The etching solution may be maintained at a temperature between about 25° C. and 90° C. while etching the first structure or. In some embodiments, the temperature of the etching solution is maintained between about 40° C. and 60° C. While higher temperatures may result in faster etching and generally improve selectivity, the process control may become more challenging. For example, elevated temperatures may cause evaporation of water and change composition of the solution. The impact of dilution and temperature on selectivity is further described below with reference to FIG. 3 and experimental data.

Method 200 may proceed with etching the hafnium oxide structure during operation 206. The hafnium oxide etching rate may be greater than the etching rate of the other structures. In other words, the etching selectivity of the other structure (e.g., a structure including silicon oxide or silicon nitride) to the hafnium oxide structure is less than one. In some embodiments, this selectivity is less than about 0.7, less than 0.5, less than 0.2, and even less than 0.1. As such, the etching rate of the other structure is about 1.5 times less than the etching rate of the hafnium oxide or, more specifically, about 2 times less, about 5 times less, and even about 10 times. In some embodiments, etching of the first structure may be completed without substantial deterioration of the other structure, e.g., the structure loosing less than 5% of its thickness.

In some embodiments, the etching rate of hafnium oxide is between 3 Angstroms per minute and 100 Angstroms per minute or, more specifically, between 10 Angstroms per minute and 100 Angstroms per minute. The etching rate of hafnium oxide may be less than 50 Angstroms per minute or even less than 20 Angstroms per minute.

Operation 206 may proceed for a predetermined period of time to ensure removal of the desired amount of hafnium oxide. In some embodiments, the hafnium oxide structure is only partially removed. Alternatively, the hafnium oxide structure may be removed completely. In this latter case, another structure positioned under the hafnium oxide structure may be made from a material that is more resistant to the etching solution than hafnium oxide. This feature ensures that the other structure is not substantially deteriorated by the etching solution once the hafnium oxide structure is completely removed.

After completion of operation 206, method 200 may proceed with rinsing and drying the substrate during operation 208. The residual etching solution is removed from the substrate surface during this operation by, for example, rinsing the surface with deionized water and drying with an inert gas, such as nitrogen or argon.

### Experimental Results

Various experiments have been conducted to determine effects of different processing conditions and etching solutions on selectivity and etching rates. Specifically, different dilution ratios and temperatures of the etching solutions have been studied including their impact on etching different materials. Two tables below summarize the result of these experiments. The first table presents etching rates of different materials exposed to different etching solutions and different temperatures. Specifically, the first table etching rates (expressed in Angstroms per minute) of hafnium oxide samples formed using ALD, silicon oxide samples formed using thermal oxidation of silicon, silicon oxides samples formed using PECVD, silicon nitride samples formed using low pressure CVD, and silicon nitride samples formed using ALD. The etching rates are grouped into four sets, each representing a different temperature conditions expressed in degrees Celsius, i.e., 25° C., 40° C., 60° C., and 80° C. Furthermore, each set include etching rates corresponding to different dilution of etching solutions used, i.e., 1000:1, 2000:1, 3000:1, 4000:1, and 5000:1.

TABLE
Etching Rate Values

| | | | Thermal | PECVD | LPCVD | |
|---|---|---|---|---|---|---|
| Dilution | Temperature | HfOx | SiOx | SiOx | SiN | ALD SiN |
| 1000:1 | 25 | 2.8 | 0.85 | 7.0 | 0.9 | 7.9 |
| 2000:1 | 25 | 2.2 | 0.15 | 1.8 | 0.6 | 4.3 |
| 3000:1 | 25 | 1.9 | 0.09 | 0.6 | 0.4 | 2.8 |
| 4000:1 | 25 | 1.8 | 0.04 | 0.4 | 0.4 | 2.5 |
| 5000:1 | 25 | 1.7 | 0.04 | 0.2 | 0.3 | 1.8 |
| 1000:1 | 40 | 4.1 | 1.21 | 9.7 | 2.0 | 17.1 |
| 2000:1 | 40 | 3.0 | 0.19 | 2.3 | 1.2 | 8.6 |
| 3000:1 | 40 | 2.7 | 0.07 | 0.9 | 0.9 | 5.9 |
| 4000:1 | 40 | 2.3 | 0.04 | 0.5 | 0.7 | 4.4 |
| 5000:1 | 40 | 2.2 | 0.04 | 0.2 | 0.6 | 3.6 |
| 1000:1 | 60 | >18 | 1.68 | 15.3 | 5.9 | 42.6 |
| 2000:1 | 60 | 7.1 | 0.33 | 3.5 | 3.4 | 22.7 |
| 3000:1 | 60 | 5.3 | 0.11 | 1.3 | 2.5 | 14.2 |
| 4000:1 | 60 | 4.9 | 0.07 | 0.6 | 2.1 | 11.6 |
| 5000:1 | 60 | 3.8 | 0.05 | 0.4 | 1.9 | 9.6 |
| 1000:1 | 80 | >18 | 2.28 | 18.9 | 15.0 | 73.8 |
| 2000:1 | 80 | >18 | 0.48 | 5.2 | 8.7 | 42.2 |
| 3000:1 | 80 | 15.7 | 0.20 | 2.0 | 6.9 | 32.4 |
| 4000:1 | 80 | 8.5 | 0.10 | 1.1 | 6.0 | 25.7 |
| 5000:1 | 80 | 6.9 | 0.08 | 0.7 | 5.3 | 21.7 |

These etching rates presented in the first table above were converted into corresponding etching selectivity values, which are presented in the second table below. The hafnium oxide etching rates were used as bases for calculating these selectivity values, i.e., each value represents a hafnium oxide etching rate divided by a corresponding etching rate of another materials for a given dilution rate and a temperature. In general, higher selectivity values are desired for faster removal of hafnium oxide without substantially deteriorating the other structures.

TABLE
Selectivity Values

| | | HfOx/ | | | HfOx/ |
|---|---|---|---|---|---|
| | | Thermal | HfOx/ | HfOx/ | ALD |
| Dilution | Temperature | SiOx | PECVD SiOx | LCVD SiN | SiN |
| 1000:1 | 25 | 3.3 | 0.4 | 3.12 | 0.3 |
| 2000:1 | 25 | 14.5 | 1.2 | 3.96 | 0.5 |
| 3000:1 | 25 | 21.9 | 3.0 | 4.39 | 0.7 |
| 4000:1 | 25 | 49.2 | 4.4 | 4.90 | 0.7 |
| 5000:1 | 25 | 49.5 | 7.8 | 5.39 | 0.9 |
| 1000:1 | 40 | 3.4 | 0.4 | 2.02 | 0.2 |
| 2000:1 | 40 | 16.3 | 1.3 | 2.50 | 0.4 |
| 3000:1 | 40 | 36.4 | 3.1 | 2.93 | 0.5 |
| 4000:1 | 40 | 65.4 | 5.0 | 3.08 | 0.5 |
| 5000:1 | 40 | 62.9 | 9.4 | 3.46 | 0.6 |
| 1000:1 | 60 | >10.7 | >1.2 | >3.1 | >0.4 |
| 2000:1 | 60 | 21.6 | 2.0 | 2.07 | 0.3 |
| 3000:1 | 60 | 47.7 | 4.1 | 2.10 | 0.4 |
| 4000:1 | 60 | 69.5 | 7.7 | 2.34 | 0.4 |
| 5000:1 | 60 | 76.7 | 10.3 | 2.07 | 0.4 |
| 1000:1 | 80 | >7.9 | >1.0 | >1.2 | >0.2 |
| 2000:1 | 80 | >37.5 | >3.5 | >2.1 | >0.4 |
| 3000:1 | 80 | 79.8 | 7.7 | 2.27 | 0.5 |
| 4000:1 | 80 | 86.4 | 7.6 | 1.41 | 0.3 |
| 5000:1 | 80 | 92.0 | 9.6 | 1.30 | 0.3 |

Selectivity trends as a function of dilution for different temperatures for one material combination is presented in FIG. 3. Specifically, FIG. 3 illustrates four plots 302-308 of etching selectivity values of hafnium oxide to thermal silicon. Line 302 corresponds to selectivity values for tests performed at 25° C., line 304 corresponds to selectivity values for tests performed at 40° C., line 306 corresponds to selectivity values for tests performed at 60° C., and line 308 corresponds to selectivity values for tests performed at 80° C. The X-axis represents dilution ratios, i.e., 1000 stands for the 1000:1 dilution ratio and so on. Y-axis represents selectivity values from the second table above. At low dilution rates, i.e., 1000:1 and 2000:1, the etching selectivity varies little with temperature. At the same, the temperature is more helpful in achieving high selectivity values in more dilution solutions (i.e., 4000:1 and 5000:1). As such, a combination of higher temperatures and more diluted solutions may be used to achieve the highest selectivity for this combination of materials. Furthermore, for all temperatures, further dilution tends to increase selectivity. However, this effect seems be tapering off after 4000:1. As such, for this combination of materials, an optimal dilution ratio may be 4000:1.

### Apparatus Examples

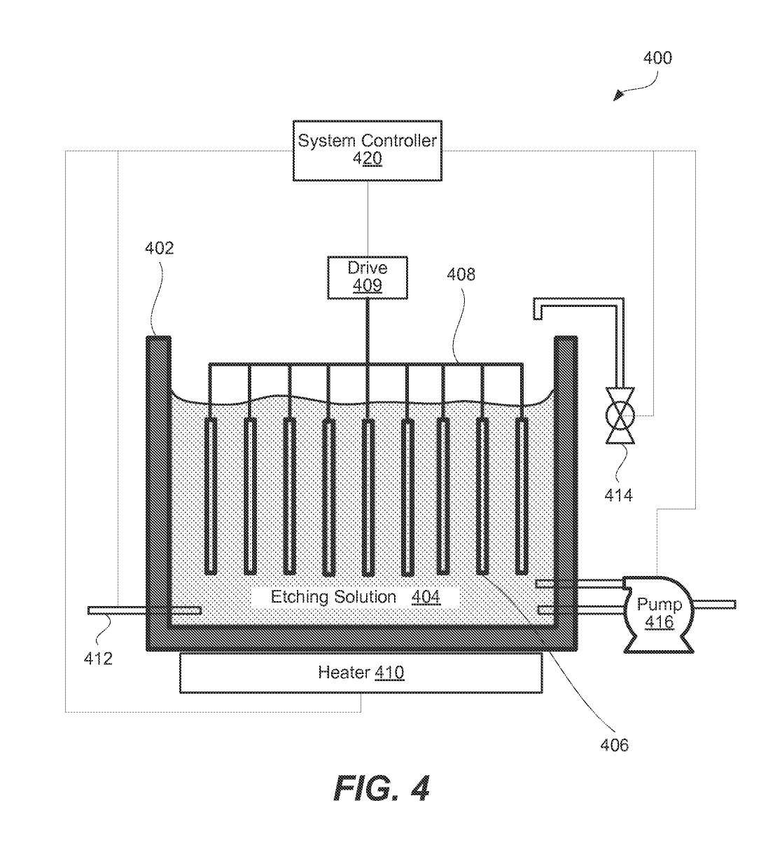

FIG. 4 illustrates a schematic representation of etching apparatus 400 for processing a semiconductor substrate to selectively remove hafnium oxide from the surface of the substrate, in accordance with some embodiments. For clarity, some components of apparatus 400 are not included in this figure. Apparatus 400 includes bath 402 for containing etching solution 404. One or more semiconductor substrates 406 may be submerged into etching solution 404 for processing or, more specifically, for removal of silicon nitride structures. Substrate 406 may be supported by substrate holder 408, which may be attached to drive 409 for moving substrate holder 408. Specifically, substrate holder 408 may be moved to submerge substrates 406 into etching solution 404 for processing, remove substrates 406 from etching solution 404 after processing, and/or to move substrates 406 within etching solution 404 during processing (e.g., to agitate etching solution 404).

Apparatus 400 also includes heater 410 and temperature sensor 412 (e.g., a thermocouple) for maintaining etching solution 404 at a predetermined temperature. Heater 410 and temperature sensor 412 may be connected to system controller 420, which may control power supplied to heater 410 based on signals received from temperature sensor 412. Various features of system controller 420 are described below.

Apparatus 400 may also include a liquid delivery system 414 for supplying additional liquids and controlling the composition of etching solution 404. For example, some components of etching solution 404 may evaporate from bath 402, and these components may be replenished in bath 402 by liquid delivery system 414. Liquid delivery system 414 may be connected to and controlled by system controller 420. Various sensors (e.g., conductivity sensor, weight sensor) may be used to provide signals about potential changes in composition of etching solution 404. Apparatus 400 may be also equipped with pump 416 for recirculating etching solution 404 in bath 402 and other purposes. Pump 416 may be also connected to and controlled by system controller 420.

Apparatus 400 may include system controller 420 for controlling process conditions during silicon nitride etching processes. Controller 420 may include one or more memory devices and one or more processors with a central processing unit (CPU) or computer, analog and/or digital input/output connections, stepper motor controller boards, and the like. In some embodiments, controller 420 executes system control software including sets of instructions for controlling timing of operations, temperature of etching solution 404, composition of etching solution 404, and other parameters. Other computer programs and instruction stored on memory devices associated with controller may be employed in some embodiments.

### CONCLUSION

Although the foregoing concepts have been described in some detail for purposes of clarity of understanding, it will be apparent that some changes and modifications may be practiced within the scope of the appended claims. It should be noted that there are many alternative ways of implementing the processes, systems, and apparatuses. Accordingly, the present embodiments are to be considered as illustrative and not restrictive.

What is claimed is:

1. A method for processing semiconductor substrates, the method comprising:
providing a semiconductor substrate comprising a first structure and a second structure,
the first structure comprising hafnium oxide,
the second structure comprising one of silicon nitride or silicon oxide;
exposing the semiconductor substrate to an etching solution,
the etching solution comprising hydrofluoric acid and water,
wherein a volumetric ratio of water to hydrofluoric acid in the etching solution is between 1000:1 and 10,000:1; and
etching the first structure,
wherein an etching rate of the first structure is greater than an etching rate of the second structure.

2. The method of claim 1, wherein an etching selectivity of the second structure to the first structure is less than 0.7.

3. The method of claim 1, wherein an etching selectivity of the second structure to the first structure is less than 0.5.

4. The method of claim 1, wherein an etching selectivity of the second structure to the first structure is less than 0.2.

5. The method of claim 1, wherein the volumetric ratio of water to hydrofluoric acid in the etching solution is between 3,000:1 and 10,000:1.

6. The method of claim 1, wherein the volumetric ratio of water to hydrofluoric acid in the etching solution is between 5,000:1 and 10,000:1.

7. The method of claim 1, wherein the etching solution is held at a temperature of between 25° C. and 90° C. during etching.

8. The method of claim 1, wherein the etching solution is held at a temperature of between 40° C. and 60° C. during etching.

9. The method of claim 1, wherein an etching rate of the first structure is between 3 Angstroms per minute and 100 Angstroms per minute.

10. The method of claim 1, wherein an etching rate of the first structure is between 10 Angstroms per minute and 100 Angstroms per minute.

11. The method of claim 1, wherein an etching rate of the first structure is less than 20 Angstroms per minute.

12. The method of claim 1, wherein the second structure comprises silicon oxide and is formed by depositing silicon oxide using thermal oxidation of silicon substrate.

13. The method of claim 12, wherein an etching selectivity of the second structure to the first structure is less than 0.02.

14. The method of claim 1, wherein the second structure comprises silicon oxide and is formed by depositing silicon oxide using plasma enhanced chemical vapor deposition (PECVD).

15. The method of claim 14, wherein the etching rate of the first structure is between 2 and 10 greater than the etching rate of the second structure.

16. The method of claim 1, wherein the second structure comprises silicon nitride and is formed by depositing silicon nitride using low pressure chemical vapor deposition (LPCVD).

17. The method of claim 16, wherein the etching rate of the first structure is between 1.5 and 6 greater than the etching rate of the second structure.

18. The method of claim 1, wherein the first structure is only partially removed during etching of the first structure.

19. The method of claim 1, wherein the etching solution further comprises hydrochloric acid.

20. A method for processing semiconductor substrates, the method comprising:
providing a semiconductor substrate comprising a first structure and a second structure,
the first structure comprising hafnium oxide,
the second structure comprising silicon oxide,
wherein the first structure and the second structure form a portion of a metal oxide semiconductor (MOS) transistor device;
exposing the semiconductor substrate to an etching solution,
the etching solution comprising hydrofluoric acid and water,
wherein a volumetric ratio of water to hydrofluoric acid in the etching solution is between 1000:1 and 10,000:1; and
partially etching the first structure,
wherein an etching selectivity of the second structure to the first structure is less than 0.1, and
wherein an etching rate of the first structure is between 3 Angstroms per minute and 20 Angstroms per minute.
